(19) United States
(12) Patent Application Publication
(10) Pub. No.: US 2013/0249588 A1
(43) Pub. Date: Sep. 26, 2013

(54) DEVICE AND METHOD FOR TESTING A SOLAR MODULE

(71) Applicant: KOMAX HOLDING AG, Dierikon (CH)

(72) Inventor: Bruno Daugy, St. Maximin (FR)

(73) Assignee: KOMAX HOLDING AG, Dierikon (CH)

(21) Appl. No.: 13/776,920

(22) Filed: Feb. 26, 2013

(30) Foreign Application Priority Data
Mar. 22, 2012 (DE) 102012102456.1

(51) Int. Cl. G01R 31/26

(52) U.S. Cl. CPC G01R 31/2605
USPC 324/757.04

(57) ABSTRACT

A test device for testing a solar module includes a transfer unit for transporting the solar module through the test device, an irradiation unit for irradiating the solar module, an imaging unit for optically capturing an image of the solar module and a tapping device for sensing parameters of the solar module and/or for supplying voltage to the solar module. The tapping device includes a contact bar on which a contact surface positioned on the solar module can glide or slide along during the transport process in order to generate an electrical connection. The contact surface is provided by a contact device that can be temporarily attached to the solar module.

### CROSS-REFERENCE TO RELATED APPLICATION

This application claims priority to German Patent Application No. 102012102456.1 filed Mar. 22, 2012.

### FIELD

The invention concerns a device and a method for testing a solar module.

### BACKGROUND

By means of a solar module it is possible to transform light into electric power. Solar modules consist of a plurality of interconnected solar cells. The power generated by the solar cells is collected by means of long metal bands and collected to a connecting zone having a positive and a negative terminal. Frequently, solar modules are equipped with so-called terminal boxes in the range of the connecting zone from which the power generated can simply be taken,

During or after production solar modules have to be tested in order to recognize defective or damaged solar cells or insufficient electrical connection between the solar cells. Different testing methods are known and customarily used for this purpose. When using the so-called electroluminescence method the solar module is supplied with voltage. The light emitted by the solar cells is captured by one or several cameras and then analyzed. For example, the electroluminescence method was described in the U.S. Pat. No. 7,601,941, wherein here merely particular solar cells were tested. In a different well-known method the solar module is irradiated (“solar simulation”), the electrical parameters of the solar module thus irradiated are captured, resulting in a current-voltage characteristic. In the methods mentioned above, the solar module has to be electrically connected with the respective test device.

The published application EP 2 330 631 A1 discloses a test device for testing a solar module according to the electroluminescence method. The test device has a plurality of cameras which can be displaced by a motor. The solar module reaches the test device, is stopped at a predetermined position in the region of the opening of a darkroom equipped with the cameras and then connected with a power source for the electroluminescence test. This test device has several disadvantages. For example, it has a comparatively complicated design and is interference-prone. In addition, the test method is expensive and time consuming.

Therefore it is the objective of the invention to avoid the disadvantages of the known devices and to provide an arrangement and a method for testing a solar module that are especially characterized by improved efficiency. In particular, it is intended to reduce the duration of the testing method. By means of the arrangement, it should especially be possible to perform an electroluminescence testing method or solar simulation. Furthermore, the arrangement should provide the possibility of selectively testing solar modules with different testing methods (for example, electroluminescence methods, solar simulation). Ultimately the arrangement should be easy to manage and operate.

### SUMMARY

The arrangement for solving the above problems is characterized in that it comprises a test device with a transfer unit by means of which the solar module can be transported through the test device. For example, by means of the transfer unit the solar module can be transported through an irradiation unit for performing a solar simulation, or through an imaging unit equipped with one or several CCD cameras for performing the electroluminescence test. Moreover, the test device comprises a device for tapping parameters of the solar module (subsequently also called “tapping device”), for example, to perform solar simulation. Alternatively or possibly additionally, the test device can comprise a device for supplying electricity to the solar module (“supply device”), for example, to perform an electroluminescence method. The tapping and/or supply device is designed to generate an electrical connection in such a way that, during the process of transporting the solar module through the test device, the tapping or supply device comes in direct or indirect contact with the solar module. Accordingly, when transporting the solar module with the transfer unit an automatic contact takes place between the solar module moving in transport direction and the tapping or supply device which is preferably stationary at least during the transport process. With such an arrangement the period of testing a solar module can be considerably reduced. The electrical connection is generated merely through the contact of two components and not, for example, through a plug connection. Therefore, the test device can have a simple structure and is easy to use.

In a first embodiment the test device can comprise an irradiation unit for irradiating the solar module. For this purpose, the above-mentioned device is designed as a tapping device for tapping parameters of the solar module irradiated by means of the irradiation unit. With such a design, the tapping device comes in direct or indirect contact with the solar module when the solar module is passing the irradiation unit, allowing for a simple and optimal solar simulation. In this way, it is especially easy to tap the voltage and current of the irradiated solar module in order to determine the current-voltage characteristic.

Alternatively or additionally, the test device can comprise an imaging unit for optically capturing the solar module in a monitoring area. In this case, the device can be designed as supply device by means of which voltage can be applied to the solar module. With this arrangement, an electroluminescence test can be performed in an easy and efficient manner. For this purpose, the supply device is designed in such a way that the solar module comes directly or indirectly in contact with the supply device when the solar module passes the monitoring area or when the solar module is transported through or past the imaging unit.

The tapping or supply device can involve a contact bar on which a contact surface attached to the solar module can glide or slide along during the transport process. When solar modules have several connecting zones arranged next to each other in transport direction, it is also possible to provide several contact bars. When the solar module with the transfer unit can be transported in a transport direction through the test device, the contact bar extends preferably in the transport direction. By means of the contact bar, it is possible to generate an electrical connection between solar module and test device over a comparatively long period of time. Instead of providing contact bars that extend in the transport direction, different components can be used as tapping or supply devices which touch only briefly the contact surface attached to the solar module. In order to ensure a safe and interference-free operating method, it can be of advantage when the contact bar comprises a feed section produced through a curve. Furthermore, the contact bar can comprise a straight contacting portion adjoining the feed section and extending in the transport direction. Moreover, the contact bar can also be bent open at its rear end (in relation to the transport direction).

In particular, it can be advantageous when the contact bar is formed of at least one strap-shaped profile element consisting of steel, copper or any other electrically conductive material. The contact bar can comprise two adjacent profile elements. By means of the pair of profile elements, the positive terminal and the negative terminal can be connected on an individual basis, respectively.

For a large-scale application, it can also be advantageous when the tapping or supply device can be positioned by means of an adjustment mechanism located in the test device. As a result, it is possible to test different size solar modules with the same test device.

When by means of the irradiation unit a lighting zone in the solar module can be irradiated, it can be of advantage to arrange the contact bar in the transport direction overlapping to the lighting zone. The overlapping relates to a top view on the test device (vertical viewing direction).

During the transport process, the tapping or supply device can come in direct contact with the connecting zone or its conductive paths. At the same time, the connecting zone can have exposed conductive paths where the metal bands connecting the solar cells are bundled. However, it can be of special advantage when the arrangement comprises a contact device that can be temporarily attached to the solar module in the area of the connecting zone, by means of which contact device the solar module can be electrically connected with the tapping or supply device. The contact device can be used also when the solar module comprises an already wired terminal box in the area of the connecting zone. Consequently, by means of the contact device an indirect contact takes place between solar module and tapping or supply device. After completing the test the contact device can simply be removed. Based on its weight, it can be especially advantageous merely to place the contact device on, or attach it to the solar module.

Consequently, the contact device can provide the contact surface that can be moved during the transport process along the contact bar in gliding or sliding manner. At the same time, the contact surface can be advantageously arranged in the area of an upper surface of the contact device. The contact device can comprise a plastic housing. By means of said housing, the contact device is electrically insulated to the outside so that operating personnel can easily and safely grab the contact device. In addition to simplify handling, a further advantage involves that it is virtually impossible that the active surface of the solar module is mechanically damaged by the tapping or supply device and especially by the contact bar.

The contact device can comprise at least one contact pin for directly contacting a conductive path of the connecting zone of the solar module or an electrical input, for example, in the form of sockets for connecting a solar module pre-assembled with a terminal box. Usually, solar modules have two conductive paths involving one terminal (positive, negative), respectively. Therefore, the contact device preferably comprises two contact pins for contacting the conductive paths. Therefore, the contact device can have a contact pin for each conductive path. In order to improve the contact quality to the solar module, the contact device can have two, three or more contact pins, respectively, each of which is attached to a conductive path of the solar module, or touches it when disconnected.

In order to generate a sliding contact to the guide rail, the contact device can comprise at least one contact element that resiliently adjoins, or can adjoin, the contact bar. The contact element can consist of steel, preferably stainless steel, copper or any other electrically conductive material. At the same time, the contact element forms an advantageous contact surface which contacts the contact bar in a sliding manner during the transport process. To provide the suspension, it is possible to use for each contact element one or several compression springs or any other means of resilience. The spring-loaded contact element can be stored in a movable manner in a housing, especially in a plastic housing. Such an arrangement ensures an excellent electrical connection between the solar module and the test device. For example, the contact element attached to the respective terminal and the at least one corresponding contact pin can be connected with one another by means of an electric wire.

The contact device can have a lower surface facing the solar module. The contact device can comprise means arranged in or on the lower surface that protect the upper surface of the solar module against scratching and/or fix the position of the contact device on the solar module. The scratch protection means can consist of an elastic material and preferably have a tubular, deformable design.

The contact device can be placed manually on the solar module. However, it is also possible that the test device comprises a pick-and-place unit by means of which the contact device is automatically placed on and removed from the solar module (after completing the test).

The transfer unit can comprise means of transport for supplying preferably in a lying position the solar module to the irradiation unit and/or to the imaging unit and means of transport for removing preferably in a lying position the solar module from the irradiation unit and/or from the imaging unit.

The means of transport can be designed as conveyor bands on which the solar modules are placed and transported in a simple and gentle manner in the transport direction through the test device. Each of the conveyor bands can comprise endless belts and two guide rollers. Additional rollers for supporting the belts of the conveyor band can be arranged between the guide rollers. However, it is also possible to use different means of transport. For example, the test device could comprise feed rollers driven by a motor and freely rotating rollers, on which the solar modules can be placed and transported.

The means of transport can be interrupted in the region of a monitoring area. In the monitoring area, the solar module can be optically captured with the imaging unit. In the case of a test device equipped with a contact bar extending in the transport direction, it can be advantageous when the contact bar extends across and is overlapping the entire monitoring area. The transfer unit can comprise two conveyor band units (supply conveyor band, discharge conveyor band). Each conveyor band unit can comprise at least two conveyor bands arranged in parallel to one another, and the solar modules can be placed on the edges of the conveyor bands. In the case of large- scale solar modules, it can be advantageous when a third conveyor band is arranged approximately in the center between the two conveyor bands.

According to the invention, the method involves the following steps: advantageously, the solar module is transported through the test device by using the transfer unit of the test device described above. The solar module transported through the test device is irradiated with artificial light and the parameters of the irradiated module are tapped by means of a tapping device which comes in direct or indirect contact with the solar module to generate an electrical connection. In this way, a simple and fast solar simulation can be performed with the solar module, thus testing the solar module. As an alternative to solar simulation, it is also possible to perform an electroluminescence method. For this purpose, the solar module to which voltage has been applied by means of a supply device is optically captured by an imaging unit. In order to generate the required electrical connection, the supply device comes in contact with the solar module during the transport process of the solar module through or past the imaging unit. In other words, the electrical connection is generated merely by the transport process. The solar module does not have to come to a stop in the test device in order to apply voltage to the solar module, which would delay the period of testing.

The direct or indirect contact comes about in that a contact or a sliding contact takes place between a stationary supply device, or a stationary tapping device, and the moving solar module. For an indirect contact, it is possible to use the contact device described above.

### DESCRIPTION OF THE DRAWINGS

The subsequent description of embodiments and the drawings show further characteristics and advantages of the invention. It is shown:

FIG. 1 is a top plan view of a solar module;

FIG. 2 is a cross section view of a test device according to the invention for testing the solar module shown in FIG. 1;

FIG. 3 is a perspective view of the tapping device shown in FIG. 2 with contact bars for contacting the solar module;

FIG. 4 is a perspective view of the test device shown in FIG. 2;

FIG. 5 is a perspective, detailed view of the contact device shown in FIG. 3 coming into contact with the contact bars;

FIG. 6 is a different perspective of the contact device shown in FIG. 5;

FIG. 7 is a rear perspective view of the contact device shown in FIG. 5;

FIG. 8 is a top plan view of the tapping device shown in FIG. 3;

FIG. 9 is an alternative to the arrangement shown in FIG. 8; and

FIG. 10 is a further alternative design of tapping device for testing the solar module.

### DETAILED DESCRIPTION

The following detailed description and appended drawings describe and illustrate various exemplary embodiments of the invention. The description and drawings serve to enable one skilled in the art to make and use the invention, and are not intended to limit the scope of the invention in any manner. In respect of the methods disclosed, the steps presented are exemplary in nature, and thus, the order of the steps is not necessary or critical.

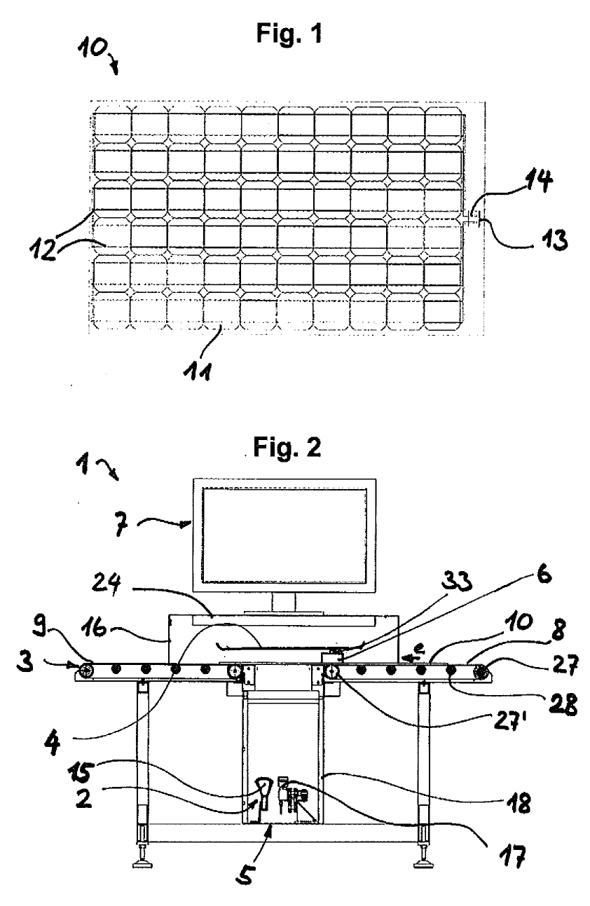

FIG. 1 shows an exemplary solar module 10 that can be tested with the test device described below. The solar module comprises a plurality of solar cells 11 which are arranged on a glass plate. The solar cells 11 are electrically connected with one another by means of soldered metal bands 12. On one side of the solar module 10, the metal bands 12 are conducted to a connecting zone 13, and there they are combined into two conductive paths 14. The solar module 10 comprises an optically active surface and an opposite rear side. At least most of the solar modules currently used have the connecting zone 13 on the rear side.

It is certainly also possible to test with the invention-based test device other embodiments of solar modules, as well as solar modules in various stages of production. It is possible to insert a plastic sheet between the glass plate and the solar cells 10 which fuses when laminating the solar module. Usually additional layers are arranged on the rear side of the solar cells before the solar module is laminated. The test can also be made after a solar module has been laminated. However, this has the disadvantage that defects can no longer be corrected. Also known are so-called thin-film modules in which the semiconducting material of the solar cells is directly applied to the glass plate. The test device described below can also be used for testing such types of modules.

FIG. 2 shows a lateral cross-section of the test device (depicted with numeral 1) for testing a solar module 10. The test device 1 shown comprises an imaging unit 5 for optically capturing the solar module from below and an irradiation unit 2 for irradiating the solar module from above. Furthermore, the test device 1 comprises a transfer unit 3 by means of which the solar module 10 can be transported in a horizontal plane in a direction e through the test device between the imaging unit 5 and the irradiation unit 2. FIG. 2 also shows the monitor of an evaluation unit 7 by means of which the images taken with a camera 17 can be analyzed.

Basically, the irradiation unit 2 consists of a light source 15 (depicted symbolically), which is arranged in a darkroom or housing 18 and provides a lighting zone. By means of the irradiation unit 2, the solar module 10 can be exposed to artificial light, and the current and voltage values thus obtained can be recorded for determining a current-voltage characteristic. For this purpose, the test device 1 is equipped with a tapping device 4 extending in the direction e, which is subsequently shown and described in more detail. However, the same device 4 can be used to apply voltage to the solar module in order to perform an electroluminescence test. The imaging unit 5 equipped with the camera 17 is used to record the electroluminescence processes. As a result, it is possible to use the arrangement shown in FIG. 2 to perform with one and the same equipment two different test methods (i.e., electroluminescence test and solar simulation).

The tapping device (depicted with numeral 4) can be used for supplying power, as well as for tapping electrical parameters. It is certainly also possible to provide a simplified test device which is configured to perform only one of the test methods described above. Consequently, the test device could comprise either an imaging unit for optically capturing the solar module or an irradiation unit for irradiating the solar module. With the device 4, power would be supplied for performing the electroluminescence test or for tapping electrical parameters (solar simulation). As a result, a test device arranged for performing the electroluminescence test would not have an irradiation unit with a light source on the same side as the imaging unit 5.

In the embodiment shown in FIG. 2, the test device comprises a darkroom or housing 16 with a light source 24 directed to the passive rear side of the module, resulting in background lighting. The positions of the solar cells of the solar module 10 illuminated by the light source 24 could be measured by means of the camera 17 and an image processing software, this making it possible to detect broken solar cells or solar cells damaged in any other way. In simpler embodiments of the invention-based test device, the transmitted light arrangement with the light source 24 has been eliminated.

The transfer unit 3 of the test device 1 comprises conveyor bands 8 and 9 that are arranged on the input side and output side respectively. Each of the respective conveyor bands 8, 9 is provided with two guide rollers 27 and 27′. One, respectively, or possibly both of the guide rollers can be powered by a motor. Support rollers 28 are arranged between the guide rollers 27, 27′ to support the belts of the conveyor bands,

The test of a solar module 10 is performed with the optically active side facing downward. On the solar module 10 a contact device 6 is temporally located on which is moved together with the solar module. On one side, the contact device 6 is electrically connected with the solar module 10. On the other side, the contact device 6 has to be connected with the test device 1 so that the solar module can be tested. For this purpose, the contact device 6 comprises a contact element 33 which comes in contact with the stationary tapping or supply device (depicted with numeral 4) and which moves in the direction e. Depending on whether the contact element 33 presses against the tapping device, a gliding or sliding contact comes about during the transport process. Obviously, the solar module 10 does not come in direct contact with the tapping device 4. The contact takes place in an indirect manner by means of the contact device 6 that can be temporarily attached to the solar module. After performing the test, the contact device 6 is again removed from the solar module 10.

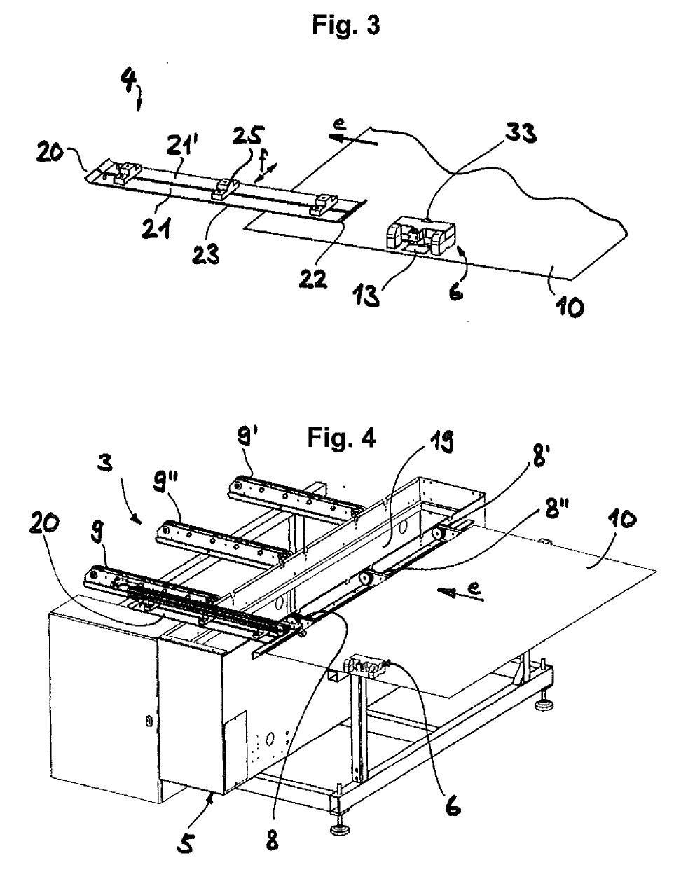

FIG. 3 shows the tapping device (depicted with numeral 4) by means of which the electrical parameters of the solar module can be sensed and power can be supplied to the solar module for performing the electroluminescence method. The tapping or supply device 4 comprises a contact bar 20 that extends in the transport direction e. The contact bar 20 comprises two parallel profile elements 21, 21′ which can consist of an electrically conductive material, for example, of steel, preferably of stainless steel, or copper. To some extent as a counterpart to the contact bar 20, the solar module 10 includes the contact device 6 in the area of the connecting zone 13. On the upper surface of the contact device 6 facing the contact bar 20 two contact elements corresponding to the profile elements 21 have been arranged, which contact elements strike and touch the contact bar 20 or its profile elements during the further process of transport in the direction e. The contact device 6 rests on the rear side of the solar module in the area of the connecting zone 13 opposite of the optically active side.

FIG. 3 shows also that the front and rear ends of the profile elements 21 and 21′ are bent upwards. The front bent up end of the contact bar 20 forms a feed section (depicted with numeral 22). The feed section 22 is followed by a straight section 23 which is basically coplanar to the upper surface of the solar module 10. In the embodiment at hand, the profile bar 20 is attached at the remaining test device (not shown here) via three suspension points by blocks 25 consisting of insulation material and electrically connected (in a manner not shown) to the test device (for example, via cables or wires). Furthermore, the test device can comprise an adjusting device (not shown) by means of which the profile bar 20 can be moved back and forth to be able to adjust to different sized and types of solar modules. The direction of movement which basically runs perpendicular to the transport direction e is indicated with a double arrow f. FIG. 8 shows the outlines of the adjustment mechanism. For example, when the size of the solar module 10 changes and with it the connecting zones or the position of the attached contact devices 6, the contact bars 20 have to be moved (moving direction indicated with an arrow f). Smaller solar modules and contact bars moved to adjust to the changed conditions are indicated with dotted lines.

FIG. 4 shows constructive details of the test device 1. FIG. 4 shows the test device 1 in which the darkroom 16 with the background lighting has been removed to better demonstrate the structure and mode of action of the test device. The transfer unit 3 comprises a supply unit with three conveyor bands 8, 8′, 8″ and a discharge unit with three conveyor bands 9, 9′, 9″. The solar modules 10 are placed in lying position on the three conveyor bands 8, 8′, 8″ or 9, 9′, 9″ arranged in parallel.

Between the conveyor bands 8, 8′, 8″ or 9, 9′, 9″ there is a gap which forms a monitoring area 19, over which gap the solar module can be moved safely without any danger of tilting. The camera housing 18, in which the cameras 17 required for testing are fixed or movably mounted, is located below the gap. This arrangement of conveyor bands makes it possible that a wide strip of the solar module 10 can be received without being obscured by any transport elements.

The test method is performed in the following manner: the solar module is transported together with the transfer unit 3 through the test device 1. For solar simulation the solar module 10 transported through the test device 1 is irradiated with artificial light and the parameters of the irradiated module are sensed during the transport process by means of the tapping device 4 which comes in contact with the solar module 10 to generate an electrical connection. Thus, the electrical connection required for testing is generated merely through the transport process. In this case indirect contact comes about through a mere contact between the stationary tapping device 4, on the one hand, and the moving solar module 10, on the other hand. For the electroluminescence method the electrical connection between solar module and test device is generated in an analogous manner.

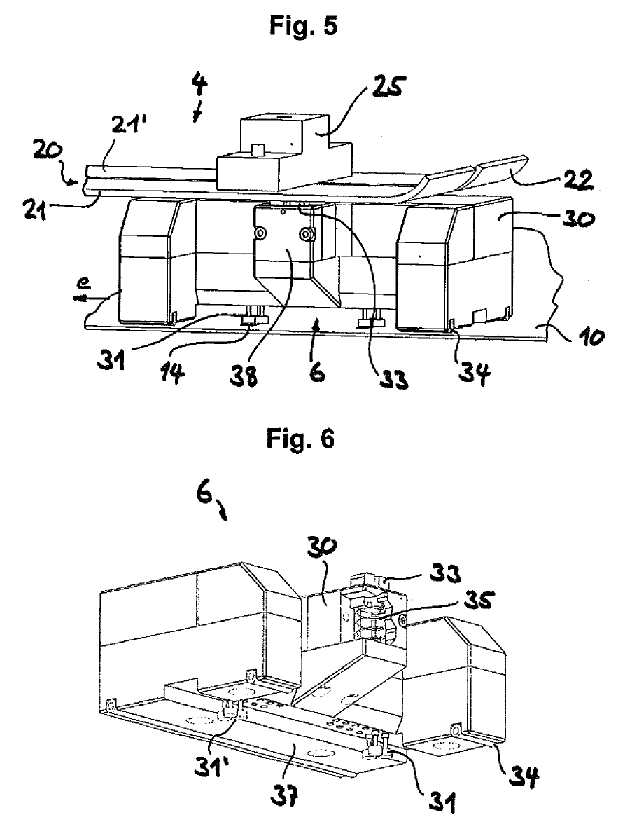

FIG. 5 shows a condition in which the solar module 10 is electrically connected with the test device. For each conductive path 14 or terminal, the contact device 6 comprises, for example, three tappet-like contact pins 31 which come in contact with or touch the conductive path. The contact pins 31 for each terminal have the advantage that the required electrical connection is ensured even when the operating personnel do not precisely place the contact device 6. However, in principle, one contact pin for each terminal would be adequate. On the other side, the contact device 6 has the two contact elements 33 which touch the profile elements 21, 21′ of the contact bar 20. The contact elements 33 are spring-loaded in the direction of the surface normal of the upper surface of the solar module 10 and are slightly pressed downwards at the start of the transport process when entering the contact bar 20. The contact elements 33 thus pressed down generate a sliding electrical contact to the bottom side of the profile of the contact bar 20 when the solar module 10 is moved in the transport direction e. The contact pins 31 can also be spring-loaded in order to ensure that all contact pins are contacted. However, the total amount of the spring force is so small that the contact device 6 cannot be lifted off the module. The contact device 6 comprises a plastic housing 30. The contact elements 33 are located in the region of the upper surface and the contact pins 31 are located on the opposite lower surface of the housing of the contact device. For each tapped terminal, the respective contact pins 31 are electrically connected with the appropriate contact element 33 (for example, via wiring behind a removable cover plate 38) inside the housing.

In FIG. 6, the plastic housing 30 has been opened up in the area of the contact element 33, making it possible to view a compression spring 35 of the spring-loaded contact element 33. The spring-loaded contact element 33 is resilient and can be moved relative to the housing 30, whereas each contact element 33 is spring-loaded with a compression spring.

According to the embodiment at hand, the contact device 6 merely has to be placed on the solar module 10. Because of its weight it remains at the position where it was placed. Additional means for fixing the contact device are not required. The bottom view representation displayed in FIG. 6 shows deformed elements 34 on the bottom side 37 of the contact device 6. Said deformed elements 34 protect the upper side of the module 10 against scratching. In addition, because of the increased friction, the scratch protection elements 34 preferably consisting of elastomer have the purpose of fixing the contact device 6 in the position in which it was placed on the solar module. The deformable elements 34 have a tubular, deformable profile. It is also possible to design the scratch protection elements 34 as flexible, solid profiles consisting of elastomer. As a result, it is almost impossible for the contact device to get out of place. When the testing method is completed, the contact device 6 is simply removed and placed on the following solar module to be tested. As shown in the subsequent figure, the contact device 6 comprises two contact elements 33 which are attached to a respective terminal of the connecting zone 13.

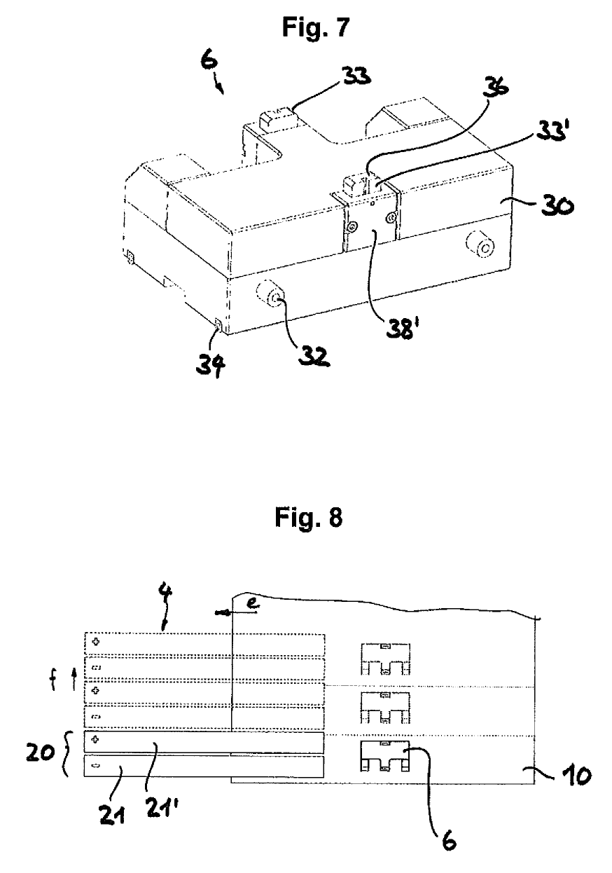

FIG. 7 shows a top view of an alternate contact device 6 which can be used with the test device 1 described above. This contact device 6 is appropriate to be used for solar modules that have been pre-assembled with terminal boxes. These solar modules have been provided with cables and plugs to be connected in a solar system. Instead of using contact pins, like in the embodiment described above, the electrical connection between solar module and contact device is generated by using an electrical connection in the form of connector sockets 32. FIG. 7 also shows that the contact device 6 is provided with two contact elements 33, 33′. Contact surfaces 36 of the contact elements that can glide along the contact bar are designed, for example, as planar surfaces. The contact surfaces 36 of the contact elements can have a convex or pointed design, resulting in a linear or punctiform mechanical contact between the contact element 33, 33′ and the contact bar 20, instead of a wide-area contact.

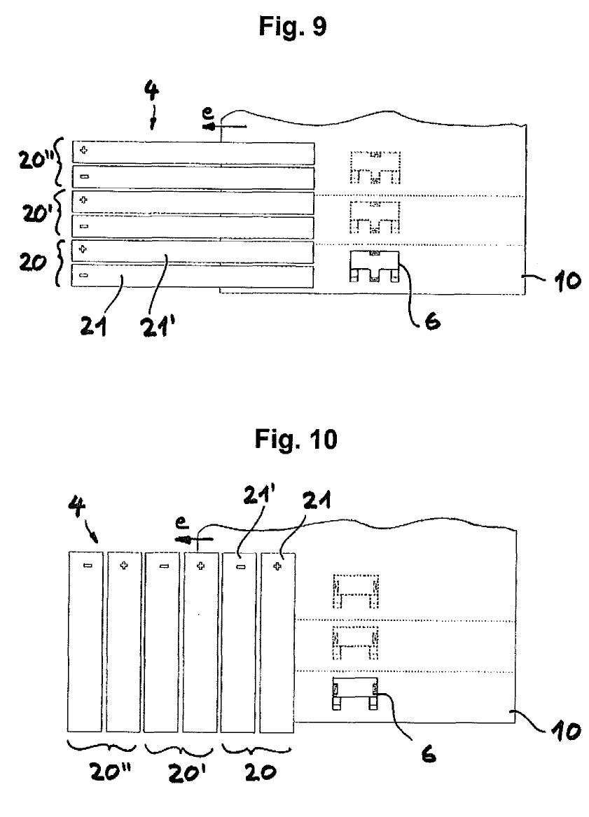

In the embodiment shown in FIG. 8, the contact bars 20 can be selectively moved laterally by means of an adjustment mechanism in the direction f transverse to the transport direction e. Instead of such a mechanism, it is also possible to provide adjacent contact bars. In the embodiment shown in FIG. 9, the tapping or supply device 4 comprises two additional rows of contact bars offset towards the inside (depicted with numerals 20′, 20″).

The test device could also comprise contact bars 20 which are aligned transverse to the transport direction. Such an arrangement is shown in FIG. 10. Here, the tapping or supply device 4 comprises three adjacent contact bars 20, 20′, 20″.

In accordance with the provisions of the patent statutes, the present invention has been described in what is considered to represent its preferred embodiment. However, it should be noted that the invention can be practiced otherwise than as specifically illustrated and described without departing from its spirit or scope.

What is claimed is:

1. A test device for testing solar modules comprising:
a transfer unit for transporting a solar module through the test device; and
a tapping device for at least one of sensing parameters of a solar module and supplying the solar module with power, wherein the tapping device contacts the solar module for generating an electrical connection as the solar module is transported through the test device by the transfer unit.

2. The test device according to claim 1 including an irradiation unit for irradiating the solar module and wherein the tapping device senses parameters of the solar module irradiated by the irradiation unit.

3. The test device according to claim 2 wherein the irradiation unit irradiates a pre-defined lighting zone at the solar module and the tapping device includes a contact bar overlapping the lighting zone and extending in a transport direction of the solar module through the test device.

4. The test device according to claim 1 including an imaging unit for optically capturing an image of the solar module in a monitoring area of the test device, wherein the tapping device applies a voltage to the solar module through the electrical connection.

5. The test device according to claim 1 wherein the tapping device includes a contact bar against which a contact device positioned on the solar module is slidably moved during transport of the solar module through the test device.

6. The test device according to claim 5 wherein the contact bar includes a bent feed section for initially receiving the contact device.

7. The test device according to claim 5 wherein the contact bar is formed as at least one strap-shaped profile element made of an electrically conductive material.

8. The test device according to claim 5 wherein the contact bar includes two adjacent profile elements.

9. The test device according to claim 1 wherein the tapping device is selectively movable in a direction transverse to a direction of transport of the solar module through the test device.

10. The test device according to claim 1 wherein the solar module has a connecting zone and the test device includes a contact device removably positioned on the solar module at the connecting zone to electrically connect the solar module with the tapping device.

11. The test device according to claim 10 wherein the contact device includes at least one contact pin for contacting a conductive path of the connecting zone of the solar module or a connector socket for electrically connecting to a terminal box of the solar module.

12. The test device according to claim 10 wherein the contact device includes at least one contact element that resiliently engages a contact bar of the tapping device with a sliding contact.

13. The test device according to claim 10 wherein that the contact device has a lower surface facing the solar module with deformed elements arranged for at least one of protecting an upper surface of the solar module against scratches and fixing a position of the contact device on the solar module.

14. The test device according to claim 13 wherein the deformed elements are formed of an elastic material and have a tubular, deformable profile.

15. The test device according to claim 1 wherein the transfer unit includes a conveyor for transporting the solar module in a horizontal plane between an irradiation unit and an imaging unit into, through and out of the test device.

16. The test device according to claim 15 wherein the conveyor includes a plurality of conveyor bands.

17. The test device according to claim 15 wherein the conveyor is interrupted in a monitoring area of the test device.

18. A method for testing a solar module comprising the steps of:
positioning in a horizontal plane a solar module having a connecting zone facing upwardly;
placing a contact device on the solar module at the connecting zone to generate an electrical connection between the connecting zone and a contact element of the contact device;
transporting the solar module through a test device using a transfer unit;
during the transport of the solar module through the test device, electrically connecting a tapping device with the contact element; and
while the solar module is in the test device, irradiating the solar module with artificial light from an irradiation unit and sensing parameters of the solar module with the tapping device through the contact device, or supplying voltage to the solar module from the tapping device through the contact device and optically capturing an image of the solar module with an imaging unit.

19. The method according to claim 18 wherein the tapping device is stationary relative to the solar module and has a contact bar in sliding contact with the contact device as the solar module is transported.
